(19) United States
(12) Patent Application Publication
(10) Pub. No.: US 2026/0279446 A1
(43) Pub. Date: Sep. 17, 2026

(54) TEMPERATURE COMPENSATION FOR DYNAMIC WORDLINE START VOLTAGE IN A MEMORY DEVICE

(71) Applicant: Micron Technology, Inc., Boise, ID (US)

(72) Inventors: Edric Goh, Singapore (SG); Dheeraj Srinivasan, San Jose, CA (US); Waing Pyie Soe, Singapore (SG); Karan Banerjee, Singapore (SG); Vivek Nandkishor Oza, Singapore (SG); Shyam Sunder Raghunathan, Hyderabad (IN)

(21) Appl. No.: 19/559,797

(22) Filed: Mar. 6, 2026

Related U.S. Application Data
(60) Provisional application No. 63/772,401, filed on Mar. 14, 2025.

(51) Int. Cl. G11C 16/08; G11C 16/04; G11C 16/10

(52) U.S. Cl. CPC G11C 16/08; G11C 16/0483; G11C 16/10

(57) ABSTRACT

A memory device includes a memory array with a plurality of blocks and control logic to receive a request to perform a program operation on the memory array, determine an operating temperature of the memory device, modify a previously determined calibrated wordline start voltage based on the operating temperature to form a modified start voltage, and cause the modified start voltage to be applied to the memory array during the program operation.

### RELATED APPLICATIONS

This application claims the benefit of priority from U.S. Provisional Patent Application No. 63/772,401, filed Mar. 14, 2025, which is incorporated herein by reference.

### TECHNICAL FIELD

Embodiments of the disclosure relate generally to memory sub-systems, and more specifically, relate to temperature compensation for dynamic wordline start voltage in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3 is a flow diagram of an example method of performing a dynamic wordline start voltage calibration process in accordance with some embodiments of the present disclosure.

FIG. 4 is a flow diagram of an example method of performing a program operation using temperature compensation for the dynamic wordline start voltage in a memory device of a memory sub-system in accordance with some embodiments of the present disclosure.

FIG. 5A is a graph illustrating how the temperature compensation component varies with temperature in accordance with some embodiments of the present disclosure.

FIGS. 5B and 5C are diagrams illustrating program voltage distributions using temperature compensation in accordance with some embodiments of the present disclosure.

FIG. 6 is a block diagram of an example computer system in which embodiments of the present disclosure can operate.

### DETAILED DESCRIPTION

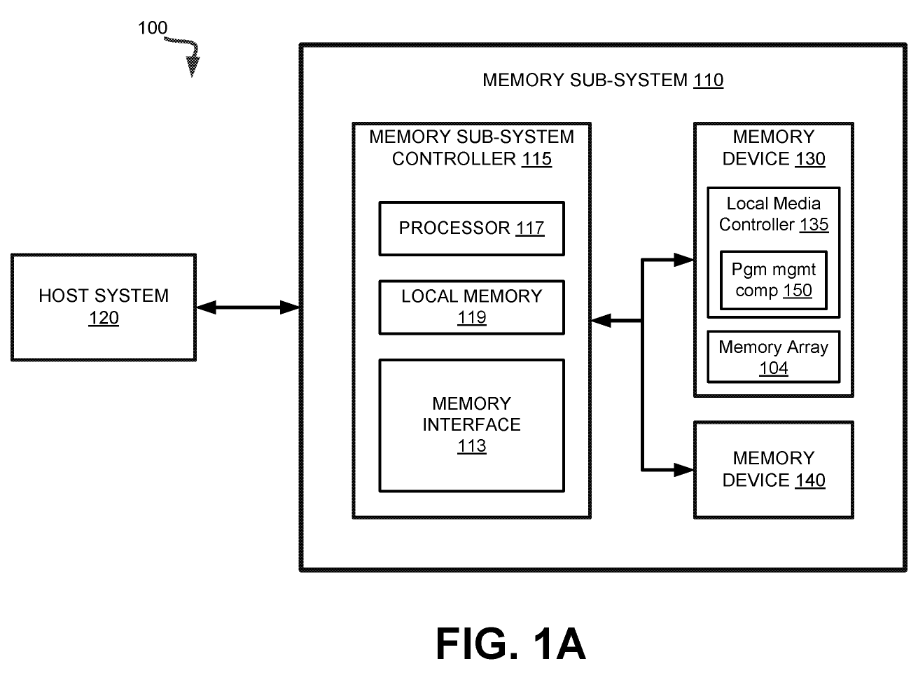

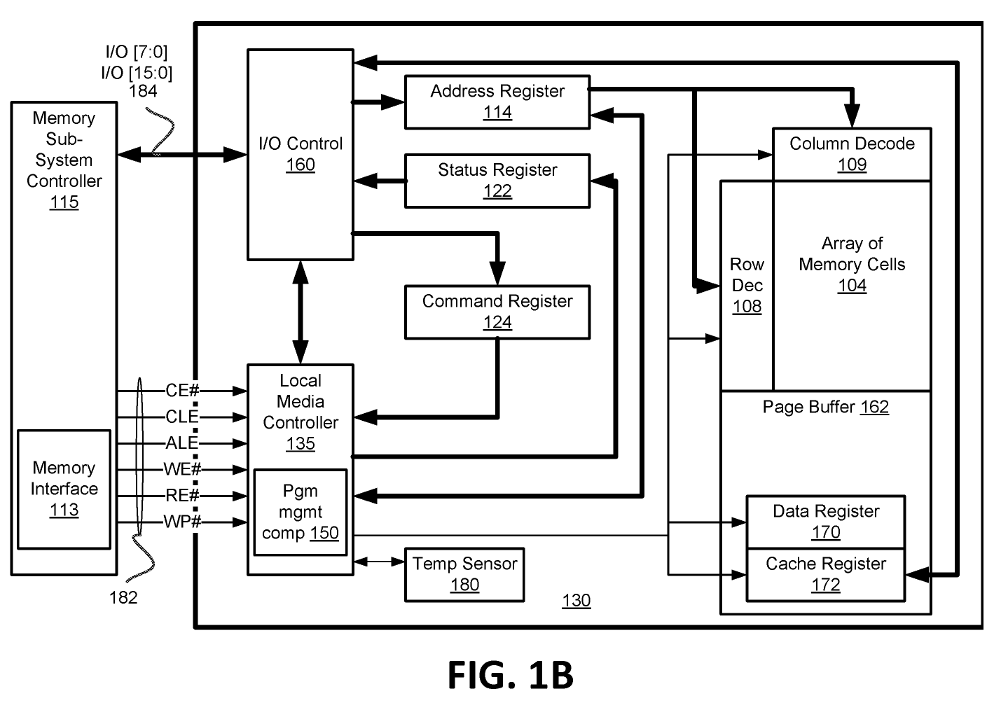

Aspects of the present disclosure are directed to temperature compensation for dynamic wordline start voltage in a memory device of a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high-density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bit lines) and rows (also hereinafter referred to as wordlines). A wordline can refer to one or more rows of memory cells of a memory device that are used with one or more bit lines to generate the address of each of the memory cells. The intersection of a bit line and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. Each data block can include a number of sub-blocks, where each sub-block is defined by an associated pillar (e.g., a vertical conductive trace) extending from a shared bitline. Memory pages (also referred to herein as “pages”) store one or more bits of binary data corresponding to data received from the host system. To achieve high density, a string of memory cells in a non-volatile memory device can be constructed to include a number of memory cells at least partially surrounding a pillar of channel material. The memory cells can be coupled to access lines, which are commonly referred to as “wordlines,” often fabricated in common with the memory cells, so as to form an array of strings in a block of memory. The compact nature of certain non-volatile memory devices, such as 3D flash NAND memory, means wordlines are common to many memory cells within a block of memory.

During a program operation on a non-volatile memory device, a selected memory cell or cells can be programmed with the application of a series of program pulses to a corresponding selected wordline. The first program pulse in the series can have a given initial voltage (e.g., a start voltage) and the voltage of each subsequent program pulse in the series may be incremented by a fixed amount. After each program pulse, or after a set of program pulses, a controller of the memory device may perform a program verify operation to determine whether the selected memory cell or cells have reached a desired logic state (i.e., a given threshold voltage level). Due to natural variations in the manufacturing process, memory cells in different segments (e.g., different blocks or different decks of the memory array) of the non-volatile memory device can require a different program voltage to be applied in order to be programmed to a given logic state. In addition, the voltage levels required for programming may change over the lifetime of the memory device. For example, as more program and erase cycles are performed on the memory cells of the memory device, the program voltage that must be applied to a given wordline in order to program the associated memory cells to a given threshold voltage level may decrease.

In order to account for the variations in the required program voltage levels in the memory device, the controller can periodically perform a wordline start voltage calibration process. For example, the memory device can calibrate the start voltage level of the first program pulse to be applied to a given segment of the memory device or at a certain point in time during the lifecycle of the memory device. In one example, such a calibration process can include first applying a predetermined initial voltage (e.g., a start voltage) and then verifying how many memory cells, if any, were programmed to the first logic state as a result of applying the initial voltage. In some embodiments, the non-volatile memory device can then proceed to increment the initial voltage by a predetermined amount (e.g., by a predetermined voltage step size), apply the updated incremented voltage, and verify how many memory cells, if any, were programmed to the first logic state. The non-volatile memory device can continue this process until sufficient memory cells are programmed to the desired state. For example, in a single-level cell system, the non-volatile memory device can continue incrementing the program voltage until at least half the memory cells are programmed to the first logic state. Accordingly, the non-volatile memory device can determine a voltage to apply to memory cells during a program operation for each segment of the memory device. In some solutions, the calibration process can also include or be referred to as resampling (e.g., if memory cells are not programmed to a desired state within a predetermined number of calibration steps, the non-volatile memory device can perform a resampling process and recalibrate the voltage applied to the memory cells). In one example, a non-volatile memory device can perform the resampling or calibration process on a first write of a new segment (e.g., block) or when transitioning from an upper deck to a lower deck of the memory device. Such a calibration process ensures that a higher program voltage than needed is not applied on the selected wordlines during a program operation, thereby preventing overprogramming and improving program performance.

Since the calibration process is relatively time consuming, it may be performed infrequently. Accordingly, a relatively long period of time may have passed after the calibration process is performed and when a program operation using the calibrated start voltage value is initiated. During that period of time, a change in the operating temperature of the memory device may also have occurred. For example, if the calibration process was performed at a first temperature, the program operation may be initiated at a second temperature that is either higher or lower than the first temperature. Such a change in temperature can impact the program voltage required to processing memory cells of the memory device to a given logic state (i.e., threshold voltage level). For example, the program voltage required at colder temperatures to program a memory cell to a given threshold voltage level is often higher than would be required at hotter temperatures. Such a change in temperature is not generally accounted for in the wordline start voltage calibration process. As such, if the calibration process to determine a calibrated start voltage value is performed at a cold temperature, and then a program operation using the calibrated start voltage value is initiated later at a hotter temperature, the calibrated start voltage value may be higher than it actually needs to be, possibly resulting in overprogramming of the memory cell or cells. Similarly, if the calibration process is performed at a hot temperature, and then a program operation is initiated later at a colder temperature, the calibrated start voltage value may be lower than it actually needs to be, which hurts program performance.

Aspects of the present disclosure address the above and other deficiencies by implementing temperature compensation for dynamic wordline start voltage in a memory device of a memory sub-system. In one embodiment, processing logic on the memory device or in the memory sub-system determines a temperature compensation component for the calibrated start voltage during the wordline start voltage calibration process. This temperature compensation component varies as a function of temperature and thus, can be recalculated when a program operation is initiated to ensure that a proper start voltage is utilized. For example, during manufacture of the memory device, a series of test/experimental operations can be performed to identify a function (e.g., a linear equation) representing how the program voltage needs to change at different temperatures. This function can be programmed to the memory device and used to determine the temperature compensation component when a program operation is performed. Accordingly, the calibrated start voltage determined during the wordline start voltage calibration process can have a fixed magnitude that is temperature agnostic. The processing logic can modify that calibrated start voltage using the newly calculated temperature compensation component, which is based on the temperature measured at the time a program operation is initiated.

Advantages of this approach include, but are not limited to, improved performance in the memory device. The use of a temperature compensation component allows the wordline start voltage calibration process to be temperature agnostic and ensures that any change in temperature that occurs after the calibration is performed will not negatively impact a subsequent program operation. The dynamically calculated temperature compensation component prevents the start voltage magnitude of the multi-pulse program operation from being too high (e.g., if the temperature has increased since calibration), thereby preventing overprogramming and possible damage to the memory cells of the memory device. It further prevents the start voltage magnitude of the multi-pulse program operation from being too low (e.g., if the temperature has decreased since calibration), thereby decreasing the overall programming time required to complete the programming operation.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

In one embodiment, local media controller 135 of memory device 130 includes program management component 150. Program management component 150 can implement temperature compensation for dynamic wordline start voltage in the memory array 104 of memory device 130. For example, program management component 150 can determine a temperature compensation component based on an operating temperature of the memory device 130 or memory sub-system 110 at a time when a program operation is initiated, and apply that temperature compensation component to modify a previously determined calibrated start voltage to be used in the program operation. Program management component 150 can then perform the program operation by applying a program voltage equal to the calibrated start voltage plus the temperature compensation component to a selected wordline on the memory array 104 and associated with one or more memory cells to be programmed to a given logic state. Further details with regards to the operations of program management component 150 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes program management component 150, which can implement temperature compensation for a dynamic wordline start voltage in memory device 130, as described herein. In one embodiment, local media controller 135 is in communication with a temperature sensor 180 disposed within or adjacent to memory device 130. Temperature sensor 180 can be used to measure an ambient temperature at certain points in time, which can represent, for example, a write temperature or a read temperature, and is otherwise referred to herein as an operating temperature.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer 162 of the memory device 130. The page buffer 162 may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

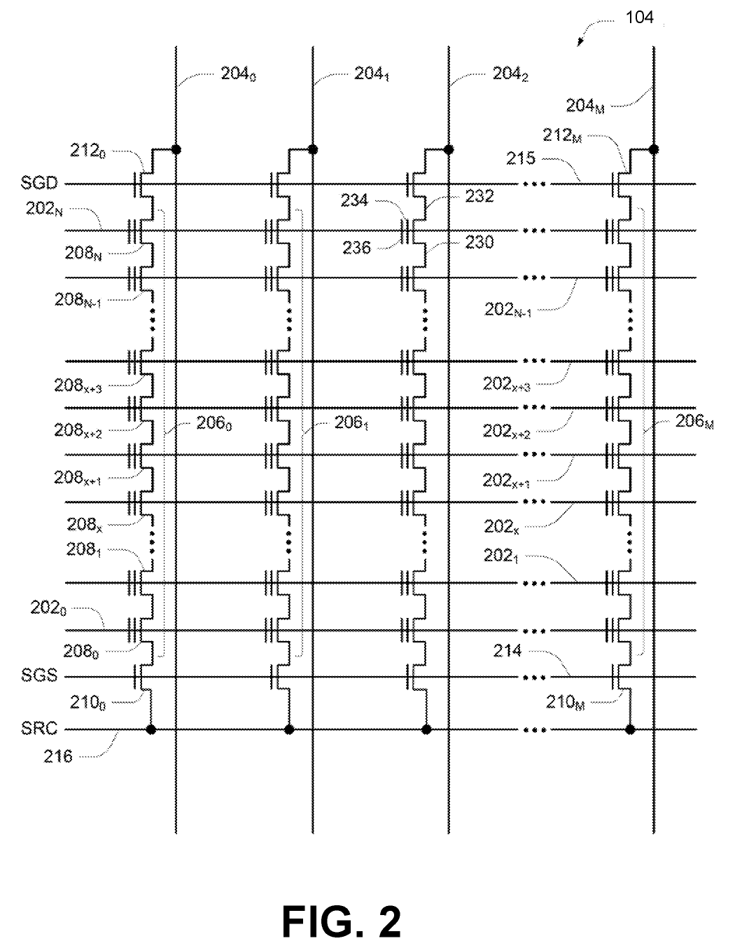

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bit lines 204₀to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀,204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅are not explicitly depicted in FIG. 2, it is apparent from the figure that the bit lines 204 of the array of memory cells 104 can be numbered consecutively from bit line 204₀to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

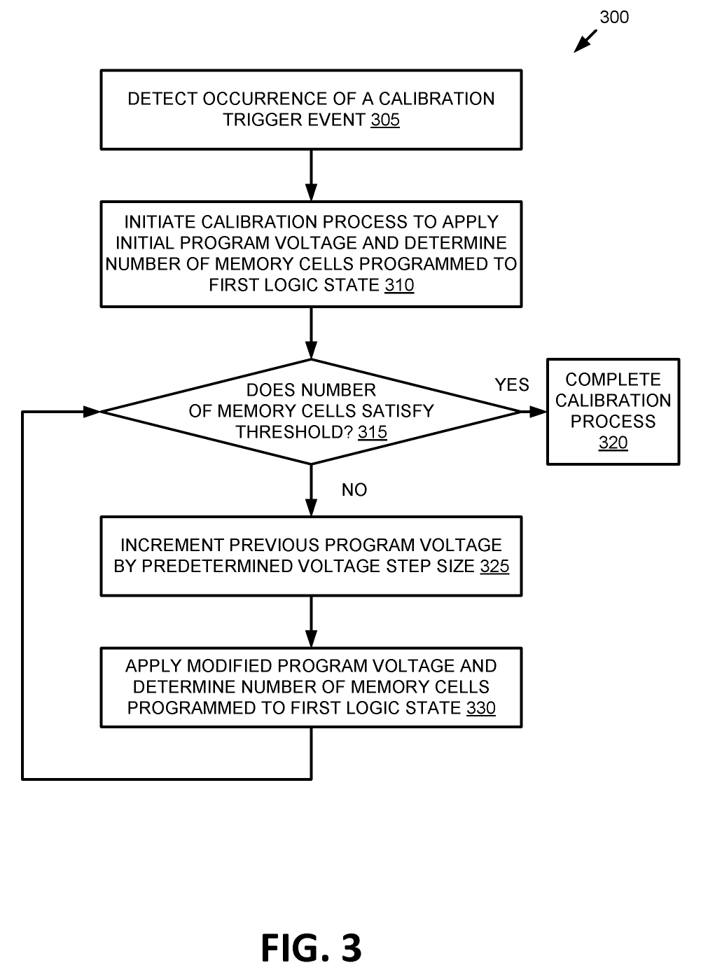

FIG. 3 is a flow diagram of an example method of performing a wordline start voltage calibration process in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by local media controller 135 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, a calibration trigger is detected. For example, the processing logic (e.g., local media controller 135) may detect the occurrence of a calibration trigger event which initiates the wordline start voltage calibration process. In one embodiment, the calibration trigger event includes receipt of a request to perform a program operation on a memory device, such as memory device 130. If the request is a first request to be received, or if a threshold period of time has expired since a previous calibration operation, then the request may be deemed a calibration trigger event.

At operation 310, a calibration process is initiated. For example, the processing logic causes the calibration process to be initiated on the memory device 130. In at least one embodiment, to perform the calibration process, the processing logic causes an initial program voltage to be applied to memory cells of a segment, such as a block, of the memory device 130. In at least one embodiment, the processing logic can then verify the program pulse and determine a number of memory cells, if any, programmed to a first logic state (i.e., a first threshold voltage level or range). In one embodiment, a magnitude of the initial program voltage is set according to an operating temperature if the memory device 130. Accordingly, the initial program voltage can be considered to include a temperature compensation component associated with the operating temperature. This ensures the result of the calibration process (i.e., a calibrated program voltage offset) that is saved, will be temperature agnostic. Thus, the calibration result is represented by the difference between the final calibrated program voltage and a base program voltage as adjusted by the temperature compensation component.

At operation 315, a determination is made. For example, the processing logic determines whether the number of memory cells programmed to a first logic state satisfy a threshold criterion. In at least one embodiment, the processing logic can compare a number of memory cells programmed to the first logic state with a threshold value. If the number meets or exceeds the threshold value, the processing logic can determine that the threshold criterion is satisfied.

If the processing logic determines the number of memory cells programmed to the first logic state satisfies the threshold criterion, at operation 320, the calibration process is completed. For example, the processing logic can complete the program operation and store the corresponding program voltage applied (e.g., the initial program voltage) as a calibrated wordline start voltage to be used in future program operations.

If, however, the processing logic determines the number of memory cells programmed to the first logic state does not satisfy the threshold criterion, at operation 325, the program voltage is incremented. For example, the processing logic can increment the initial program voltage by a predetermined step size (e.g., a step size programmed within the memory device 130 or provided by host system 120) to determine a second program voltage.

Accordingly, the processing logic can apply the second program voltage and perform a second verification operation (e.g., determine if a number of memory cells programmed to the first logic state satisfies the threshold value after the second program voltage is applied).

At operation 330, a program voltage is applied. For example, the processing logic causes a modified program voltage to be applied to memory cells of a segment, such as a block, of the memory device 130. The modified program voltage can be equal to the initial program voltage (or any previous program voltage) incremented by the predetermined step size, as described in operation 325. In at least one embodiment, the processing logic can then verify the program pulse and determine a number of memory cells, if any, now programmed to the first logic state (i.e., the first threshold voltage level or range).

Processing can return to operation 315 where the processing logic compares the number of memory cells now programmed to the first logic state with a threshold value. In at least on embodiment, the processing logic can repeat the steps described with reference to operations 315-330 until the number of memory cells programmed to the first logic state satisfies the threshold criterion. It should be noted, the processing logic can refrain from storing a program voltage if either the calibration process or resampling process fails (e.g., the processing logic can be programmed to store a program voltage upon a successful completion of a calibration or resampling process). In some embodiments, the processing logic can update a program voltage stored at the register (e.g., update the program voltage from a first value to a second value responsive to completing a successful calibration process on a second segment of the memory device utilizing the program voltage having the second value).

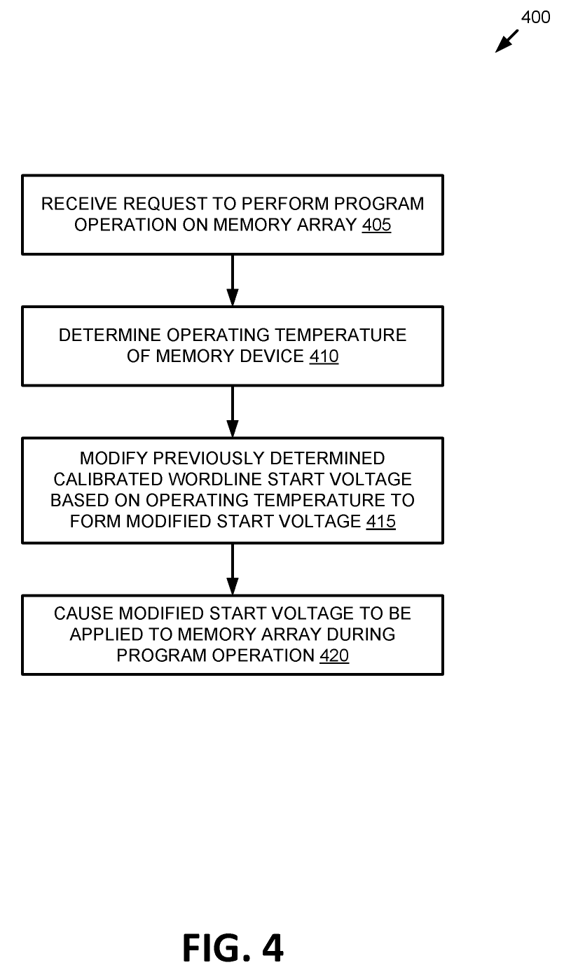

FIG. 4 is a flow diagram of an example method of performing a program operation using temperature compensation for the dynamic wordline start voltage in a memory device of a memory sub-system in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by program management component 150 of FIGS. 1A and 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, a request is received. For example, control logic (e.g., local media controller 135) can receive a request to perform a memory access operation on a memory array, such as memory array 104, of a memory device, such as memory device 130. In one embodiment, the request is received from a requestor, such as memory interface 113 of memory sub-system controller 115, or host system 120. In one embodiment, the request to perform the memory access operation includes a request to perform a program operation, such as to store data at one or more memory cells of memory array 104.

At operation 410, an operating temperature is determined. For example, the control logic can determine the operating temperature at a time when the request to perform the memory operation is received. In one embodiment, the control logic can obtain a temperature measurement value from a temperature sensor on the memory device 130, such as temperature sensor 180 (i.e., an on-die temperature sensor). Depending on the embodiment, the control logic can either query temperature sensor 180 for a new temperature measurement in response to receiving the request at operation 405, or can use a most recently measured temperature value (e.g., when temperature measurements are routinely taken at periodic intervals on memory device 130). In another embodiment, the control logic can receive a temperature measurement value from a temperature sensor external to the memory device, such as a sensor located elsewhere in memory sub-system 110.

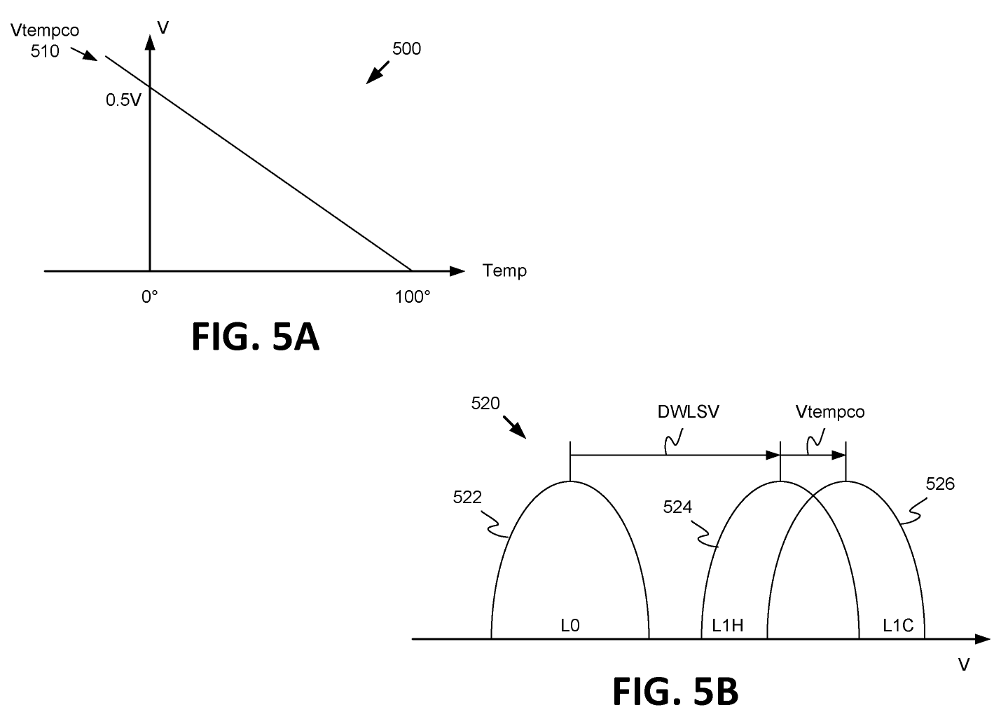

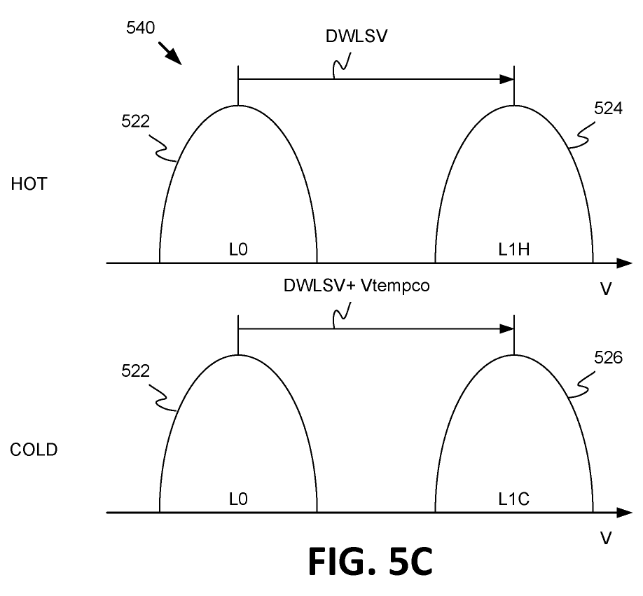

At operation 415, a voltage is modified. For example, the control logic can modify a default magnitude of a previously determined calibrated wordline start voltage signal based on the operating temperature to a form a modified start voltage signal. In one embodiment, local media controller 135 determines a temperature compensation component associated with the operating temperature. For example, local media controller 135 can apply the operating temperature to a function, which may be previously determined based on experimentation, in order to determine the temperature compensation component. In one embodiment, the function comprises a linear equation. For example, FIG. 5A is a graph 500 illustrating how the temperature compensation component (Vtempco) 510 varies with temperature in accordance with some embodiments of the present disclosure. As illustrated, the temperature compensation component 510 may be a linear function with a given slope, where the value is lower at hotter temperatures and higher at colder temperatures. Accordingly, the processing logic can determine a corresponding temperature compensation component value for any operating temperature at which the program operation is performed. Assuming that the temperature compensation component has a positive value, the processing logic can add the temperature compensation component value to the previously determined calibrated wordline start voltage (e.g., as determined using method 300) to form the modified start voltage signal. In one embodiment, the wordline voltage signal can have an initial magnitude that was previously determined as described above with respect to FIG. 3, and which is used in the absence of any temperature compensation. The initial magnitude can be set based on a default temperature (e.g., 0 degrees Celsius, a normal operating temperature, or some other temperature). In one embodiment, local media controller 135 can increase (or decrease) the initial magnitude by an amount corresponding to the temperature compensation component to generate a modified or adjusted magnitude.

Referring again to FIG. 4, at operation 420, a signal is applied during a memory access operation. For example, the control logic can cause the modified start voltage signal to be applied to the memory array 104. In one embodiment, local media controller 135 directs a signal driver to apply the modified start voltage signal to a selected wordline, such as one of wordlines 202₀ to 202_{N}, of the memory array 104. As described above, the modified start voltage signal can have a magnitude adjusted in view of the measured operating temperature of the memory device 130. For example, FIG. 5B is a diagram 520 illustrating program voltage distributions 522, 524, and 526 using temperature compensation in accordance with some embodiments of the present disclosure. In order to program a first distribution of memory cells (e.g., L1), the processing logic may apply a first voltage signal. As illustrated, the L1 distribution may be at a higher voltage level that the L0 distribution 522. The specific voltage level may vary, however, depending on the operating temperature. For example, at a relatively hot temperature, the first distribution (i.e., L1H) 524 may be at a first voltage level, while at a relatively cool temperature, the first distribution (i.e., L1C) 526 may be at a second voltage level. Without temperature compensation, the initial calibration of the wordline voltage, regardless of temperature, will result in the same threshold voltage placement. For subsequent program operations, however, if there is a change in temperature then the L1 distribution will shift based on current temperature, as shown in FIG. 5B. Accordingly, a temperature compensation component (Vtempco) may be added to the start voltage signal used in the programming operation. As illustrated in diagram of 540 of FIG. 5C, after the calibration process is performed, at the hot temperature, the temperature compensation component may be very small (e.g., close to or equal to 0V), while at the cooler temperature, the temperature compensation component may have some larger, non-zero value, thus resulting in a higher modified start voltage signal (i.e., DWLSV+Vtempco). The start voltage signal may correspond to the first program pulse in a series of pulses, where the voltage of each subsequent program pulse in the series may be incremented by a fixed amount. After each program pulse, or after a set of program pulses, local media controller 135 may perform a program verify operation to determine whether the selected memory cell or cells have reached a desired logic state (i.e., a given threshold voltage level). The program operation can continue in this manner until the desired logic state has been reached.

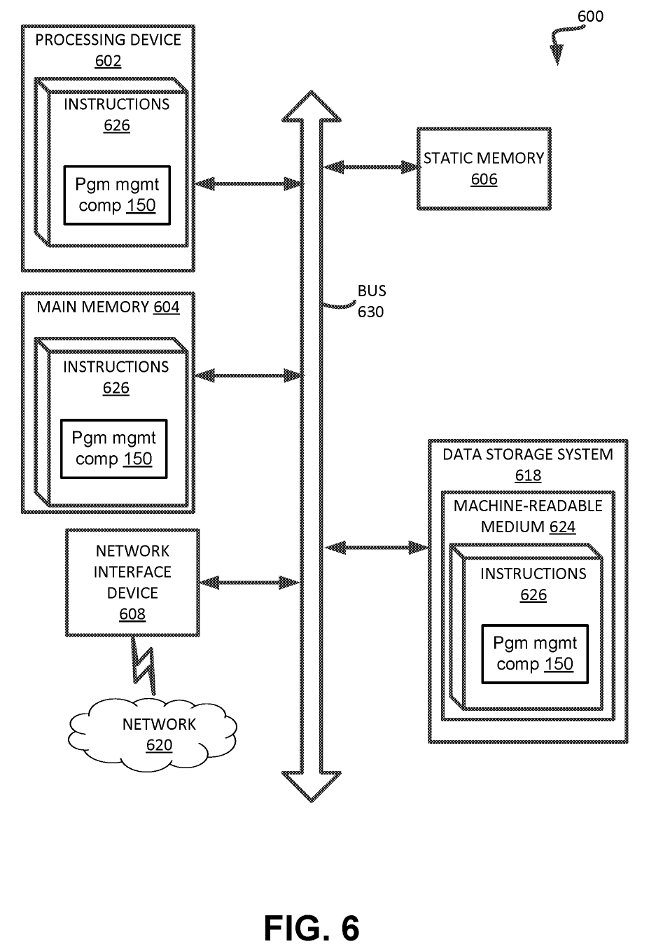

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to program management component 150 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to the program management component 150 of FIG. 1A. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array; and
control logic, operatively coupled with the memory array, to perform operations comprising:
receiving a request to perform a program operation on the memory array;
determining an operating temperature of the memory device;
modifying a previously determined calibrated wordline start voltage based on the operating temperature to form a modified start voltage; and
causing the modified start voltage to be applied to the memory array during the program operation.

2. The memory device of claim 1, wherein the memory device further comprises an on-die temperature sensor, and wherein determining the operating temperature of the memory device comprises obtaining a temperature measurement from the on-die temperature sensor.

3. The memory device of claim 1, wherein determining the operating temperature of the memory device comprises receiving a temperature measurement from a temperature sensor external to the memory device.

4. The memory device of claim 1, wherein modifying the previously determined calibrated wordline start voltage based on the operating temperature to form the modified start voltage comprises:
determining a temperature compensation component associated with the operating temperature; and
modifying the previously determined calibrated wordline start voltage by an amount corresponding to the temperature compensation component.

5. The memory device of claim 4, wherein determining the temperature compensation component associated with the operating temperature comprises applying the operating temperature to a function determined based on experimentation.

6. The memory device of claim 5, wherein the function comprises a linear equation.

7. The memory device of claim 1, wherein the previously determined calibrated wordline start voltage is determined using a calibration process, the calibration process comprising application of a sequence of program voltages, each separated by a predetermined voltage step size, and measurement of how many programmed memory cells reach a target state in response to each program voltage.

8. A method comprising:
receiving a request to perform a program operation on a memory array of a memory device;
determining an operating temperature of the memory device;
modifying a previously determined calibrated wordline start voltage based on the operating temperature to form a modified start voltage; and
causing the modified start voltage to be applied to the memory array during the program operation.

9. The method of claim 8, wherein the memory device further comprises an on-die temperature sensor, and wherein determining the operating temperature of the memory device comprises obtaining a temperature measurement from the on-die temperature sensor.

10. The method of claim 8, wherein determining the operating temperature of the memory device comprises receiving a temperature measurement from a temperature sensor external to the memory device.

11. The method of claim 8, wherein modifying the previously determined calibrated wordline start voltage based on the operating temperature to form the modified start voltage comprises:
determining a temperature compensation component associated with the operating temperature; and
modifying the previously determined calibrated wordline start voltage by an amount corresponding to the temperature compensation component.

12. The method of claim 11, wherein determining the temperature compensation component associated with the operating temperature comprises applying the operating temperature to a function determined based on experimentation.

13. The method of claim 12, wherein the function comprises a linear equation.

14. The method of claim 8, wherein the previously determined calibrated wordline start voltage is determined using a calibration process, the calibration process comprising application of a sequence of program voltages, each separated by a predetermined voltage step size, and measurement of how many programmed memory cells reach a target state in response to each program voltage.

15. A memory device comprising:
a memory array; and
control logic, operatively coupled with the memory array, to perform operations comprising:
determining an operating temperature of the memory device;
adjusting a magnitude of a previously determined calibrated wordline start voltage signal to an adjusted magnitude based on the operating temperature; and
performing a program operation on the memory array using a wordline start voltage signal having the adjusted magnitude.

16. The memory device of claim 15, wherein the memory device further comprises an on-die temperature sensor, and wherein determining the operating temperature of the memory device comprises obtaining a temperature measurement from the on-die temperature sensor.

17. The memory device of claim 15, wherein determining the operating temperature of the memory device comprises receiving a temperature measurement from a temperature sensor external to the memory device.

18. The memory device of claim 15, wherein adjusting the magnitude of the previously determined calibrated wordline start voltage signal to the adjusted magnitude based on the operating temperature comprises:
determining a temperature compensation component associated with the operating temperature; and
modifying the previously determined calibrated wordline start voltage by an amount corresponding to the temperature compensation component.

19. The memory device of claim 18, wherein determining the temperature compensation component associated with the operating temperature comprises applying the operating temperature to a function determined based on experimentation.

20. The memory device of claim 15, wherein the previously determined calibrated wordline start voltage is determined using a calibration process, the calibration process comprising application of a sequence of program voltages, each separated by a predetermined voltage step size, and measurement of how many programmed memory cells reach a target state in response to each program voltage.
